(19) United States
(12) Patent Application Publication
(10) Pub. No.: US 2019/0393250 A1
(43) Pub. Date: Dec. 26, 2019

(54) DISPLAY PANEL AND MANUFACTURING METHOD THEREFOR

(71) Applicant: SHENZHEN ROYOLE TECHNOLOGIES CO., LTD., Shenzhen (CN)

(72) Inventor: Jiangbo YE, Shenzhen (CN)

(21) Appl. No.: 16/489,555

(22) PCT Filed: May 31, 2017
(86) PCT No.: PCT/CN2017/086725

§ 371 Date: Aug. 28, 2019

(51) Int. Cl. H01L 27/12

(52) U.S. Cl. CPC H01L 27/1218; H01L 27/127; H01L 27/124

(57) ABSTRACT

A display panel includes a substrate and a plurality of thin film transistors arranged on the substrate in a matrix. The display panel further includes a photoresist layer and a shading layer, which are arranged between each of the thin film transistors and the substrate; each of the thin film transistors includes a conductive channel corresponding to the photoresist layer and the shading layer; the photoresist layer is more adjacent to the substrate than the shading layer; the shading layer is operated to reflect light transmitted from the substrate to prevent the light from being transmitted to the conductive channel; and the photoresist layer is operated to refract the light transmitted from the substrate and transmit the refracted light unidirectionally along a light outlet direction of the display panel.

### RELATED APPLICATION

The present application is a National Phase of International Application Number PCT/CN2017/086725, filed May 31, 2017.

The disclosure of the patent document contains materials protected by a copyright. The copyright is reserved by a copyright owner. The copyright owner has no objection to the reproduction of the patent document or the patent disclosure in the official records and files of the Patent and Trademark Office.

### TECHNICAL FIELD

The application relates to the field of display technologies, more particularly relates to a display panel and manufacturing method therefor.

### BACKGROUND

A display panel makes thin film transistors (TFT) or other semiconductors as switching elements of pixel units for receiving image data. It is well known that, a conductive channel of the TFT is made by semiconductors, and as light can transmitted in the whole display panel, when the semiconductors receive the light, a photoelectric effect is prone to generated. When the semiconductors of the conductive channel generate the photoelectric effect, the switching characteristics of the TFT may be affected by it. Therefore, the display panel corresponding to the conductive channel of the TFT may arrange shading materials, but the light transmitted in the display panel would be reflected multiple times due to the arrangement of the shading materials, thus decreasing light utilization.

### SUMMARY

In order to solve the above problems, the present disclosure provides a display panel with high light utilization.

Furthermore, a method for manufacturing the aforementioned display panel is provided.

An exemplary embodiment of the present disclosure provides a display panel, including a substrate and a plurality of thin film transistors arranged on the substrate in a matrix, wherein the display panel further includes a photoresist layer and a shading layer, which are arranged between each of the thin film transistors and the substrate; each of the thin film transistors includes a conductive channel corresponding to the photoresist layer and the shading layer; the photoresist layer is more adjacent to the substrate than the shading layer; the shading layer is operated to reflect light transmitted from the substrate to prevent the light from being transmitted to the conductive channel; and the photoresist layer is operated to refract the light transmitted from the substrate and transmit the refracted light unidirectionally along a light outlet direction of the display panel.

A method for manufacturing a display panel, comprising:

providing a substrate;

forming a patterned photoresist layer on a surface of the substrate;

forming a patterned shading layer on the photoresist layer, the photoresist layer having the same pattern as the shading layer; and

forming a plurality of thin film transistors arranged in a matrix on the patterned shading layer, wherein the photoresist layer and the shading layer correspond to a conductive channel of the thin film transistor;

wherein the shading layer is operated to reflect light transmitted from the substrate to prevent the light from being transmitted to the conductive channel, and the photoresist layer is operated to refract light from the substrate and transmit the refracted light unidirectionally along a light outlet direction of the display panel.

Compared with the related art, since the thin film transistors arranges a photoresist layer on one side of a light incident direction, the photoresist layer may make the light located at one side of the thin film transistor adjacent to the substrate to be unidirectionally transmitted along a light outlet direction, thereby effectively preventing light reflected by the shading layer from entering the substrate again for multiple transmissions and preventing the light loss, and thereby improving light utilization.

### BRIEF DESCRIPTION OF THE DRAWINGS

In order to more clearly illustrate the technical solutions in the exemplary embodiments of the present disclosure, the accompanying drawings used in the description of the exemplary embodiments will be briefly described below. Obviously, the accompanying drawings in the following description are only some embodiments of the present disclosure, those skilled in the art can also obtain other drawings based on these drawings without paying any creative work.

FIG. 1 is a schematic view of a side of a display panel provided by an exemplary embodiment of a first scheme of the present disclosure.

FIG. 2 is a light path diagram of light transmitted in the photoresist layers of the two adjacent thin film transistors as shown in FIG. 1.

FIG. 3 is a flowchart for manufacturing the display panel as shown in FIG. 1.

FIG. 4 is a flowchart for manufacturing a photoresist layer as shown in FIG. 1.

### DETAILED DESCRIPTION

In order to more clearly illustrate the technical solutions in the exemplary embodiments of the present disclosure, the accompanying drawings used in the description of the exemplary embodiments will be briefly described below. Apparently, the described embodiments are merely some but not all of the embodiments of the present disclosure. All other embodiments obtained by a person of ordinary skill in the art based on the embodiments of the present disclosure without creative efforts shall fall within the protection scope of the present disclosure.

The display panel includes a substrate, a photoresist layer, a shading layer, and a thin film transistor, which are sequentially stacked. The shading layer is operated to shut out the light transmitted from the substrate to the conductive channel, and the photoresist layer is operated to unidirectionally transmit the light transmitted from the substrate along a light outlet direction of the display panel to prevent the light transmitted to the shading layer from being reflected to the substrate. Furthermore, a refractive index of the photoresist layer gradually decreases along the light outlet direction of the display panel. The photoresist layer includes at least one resin material with one photosensitive group, and at least one resin material with a plurality of photosensitive groups, and the concentration of the resin material with a plurality of photosensitive groups gradually decreases along the light outlet direction of the display panel. The refractive index of the resin material with a plurality of photosensitive groups is greater than the refractive index of the resin material with one photosensitive group.

Specifically, the layered structure of the display panel will be specifically described below with reference to the accompanying drawings.

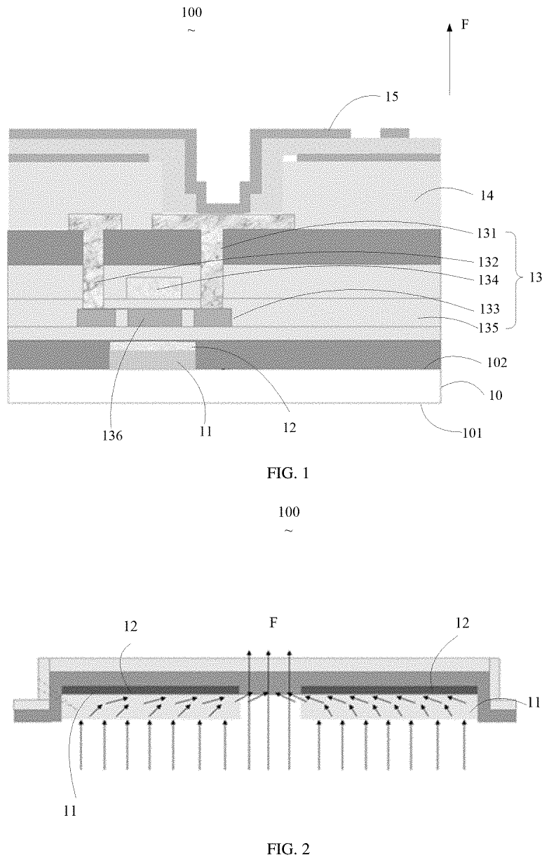

As illustrated in FIG. 1, FIG. 1 is a schematic view of a side of a display panel provided by an exemplary embodiment of a first scheme of the present disclosure. As illustrated in FIG. 1, the substrate 10 of the display panel 100 includes a first surface 101 and a second surface 102, where the first surface 101 is opposite to the second surface 102. The first surface 101 is operated to receive light, that is, the first surface 101 is configured as a light incident surface of the display panel 100. It will be apprehended that, a light source (not shown) may be arranged on one side corresponding to the first surface 101. Light emitted by the light source is configured as an image display light of the display panel 100. The second surface 102 is operated to arrange a display element (not shown), which is operated to display image by matching with the light received by the first surface 101. For illustration purposes, a first direction F is defined as a light outlet direction of the display panel 100.

In the embodiment, the substrate is a glass substrate. Of course, in an alternative embodiment, the substrate 10 may be a substrate made from another material, such as a resin substrate.

A patterned photoresist layer 11, a patterned shading layer 12, a thin film transistor 13, an insulating protection layer 14, and conductive electrodes 15 are sequentially arranged on the first surface 101.

The photoresist layer 11 is operated to make the light emitted from the second surface 102 to be unidirectionally transmitted along the first direction F.

The shading layer 12 is arranged on a surface of the photoresist layer 11, and configured to shut out the light transmitted from the photoresist layer 11.

The thin film transistor 13 is arranged on the shading layer 12 by a spaced insulating layer (not shown). The thin film transistor 13 includes a source 131, a drain 132, a semiconductor layer 133, and a gate 134. The source 131, the drain 132 are connected with the semiconductor layer 133. The source 131 and the drain 132 are arranged on the left and the right sides of the semiconductor layer 133, respectively. The semiconductor layer 133 includes a conductive channel 136 of the thin film transistor 13. The gate 134 is disposed above the conductive channel 136 with an insulating layer therebetween. In other words, the gate 134 is more far away from the second surface 102 of the substrate 10 than the source 131, the drain 132, and the semiconductor layer 133, thereby forming a top gate structure. That is, a distance between the gate 134 and the second surface 102 of the substrate 10 is greater than a distance between the source 131, the drain 132, or the semiconductor layer 133 and the second surface 102 of the substrate 10.

In the embodiment, the conductive channel 136 is aligned with the photoresist layer 11 and the shading layer 12, that is, projections of the conductive channel 136, the photoresist layer 11, and the shading layer 12 in the first direction F on the second surface 102 of the substrate 10 are lapped each other. Thereby, the shading layer 12 can effectively prevent the light received from the first surface 101 of the substrate 10 from directly illuminating the conductive channel 136, thus avoiding a photoelectric effect, which affects the operational performance of the thin film transistor 13, generated by the conductive channel 136, when the conductive channel 136 is affected by the light.

In the embodiment, the insulating layer and the gate insulating layer 135 are made from silicon nitride (SiNx) or silicon oxide (SiOx), and the source 131, the drain 132, and the gate 134 are made from a metal conductive material, such as molybdenum (Mo) or copper (Cu).

Specifically, as illustrated in FIG. 2, FIG. 2 is a light path diagram of light transmitted in the photoresist layers of the two adjacent thin film transistors as shown in FIG. 1. As illustrated in FIG. 1 and FIG. 2, a refractive index of the photoresist layer 11 gradually decreases along the light outlet direction of the display panel 100, thus the photoresist layer can refract the light transmitted from the first surface 101 to reduce the light transmitted to the shading layer 12. In addition, when the light transmits to the shading layer 12 to generate reflection, the photoresist layer 11 further refracts the light reflected by the shading layer 12, to make the refracted light to be transmitted unidirectionally in the first direction F, thus the light reflected by the shading layer 12 may be prevented from being transmitted again into the substrate 10. Therefore, the photoresist layer 11 enables the light to be unidirectionally transmitted in the first direction F corresponding to a photic region of the display panel 100, and the light may not transmit round trip for multiple times in the substrate 10 and other layers, thereby effectively improving the light utilization.

The photoresist layer 11 includes at least one resin material with one photosensitive group and at least one resin material with a plurality of photosensitive groups. The concentration of the resin material with a plurality of photosensitive groups along the light outlet direction of the display panel 100 is gradually decreased, that is, the concentration of the resin material with a plurality of photosensitive groups is gradually decreased along the first direction F, thus a refractive index of the photoresist layer 11 along the light outlet direction of the display panel 100 is gradually decreased. Preferably, the refractive index of the resin material with a plurality of photosensitive groups is greater than the refractive index of the resin material with the one photosensitive group.

Preferably, the resin material with a plurality of photosensitive groups is capable of absorbing ultraviolet light and visible light having a wavelength smaller than a preset value, thus improving the purity of the light for image display of the display panel 100.

In an alternative embodiment, the thin film transistor 13 may also be a bottom gate structure, that is, the gate 134 is disposed under the conductive channel 136 with an insulating layer 136 therebetween. In other words, the source 131, the drain 132, and the semiconductor layer 133 are more far away from the second surface 102 of the substrate 10 than the gate 134, thus forming a bottom gate structure. That is, a distance between the source 131, the drain 132, or the semiconductor layer 133 and the second surface 102 of the substrate 10 is greater than a distance between the gate 134 and the second surface 102 of the substrate 10.

Preferably, the semiconductor layer 133 is processed by a low temperature poly-silicon process (low temperature LTPS).

Compared with the related art, since the thin film transistors arranges a photoresist layer on one side of a light incident direction, the photoresist layer may make the light located at one side of the thin film transistor adjacent to the substrate to be unidirectionally transmitted along the light outlet direction, thereby effectively preventing light reflected by the shading layer from entering the substrate again for multiple transmissions and preventing the light loss, and thereby improving light utilization.

It will be apprehended that, the display panel 100 can be applied to a liquid crystal display device that needs to use a backlight, or can be applied to an Organic Light-Emitting Diode (OLED).

As illustrated again in FIG. 1, the insulating protection layer 14 and the conductive electrodes 15 are sequentially arranged on a surface of the thin film transistor 13. The insulating protection layer 14 corresponding the source 131 of the thin film transistor 13 defines an opening (not labeled), thus the conductive electrodes 15 can be electrically connected with the source 131.

In the embodiment, the insulating protection layer 14 is made from silicon nitride (SiNx) or silicon oxide (SiOx), and the conductive electrodes 15 are made from indium tin oxide (ITO).

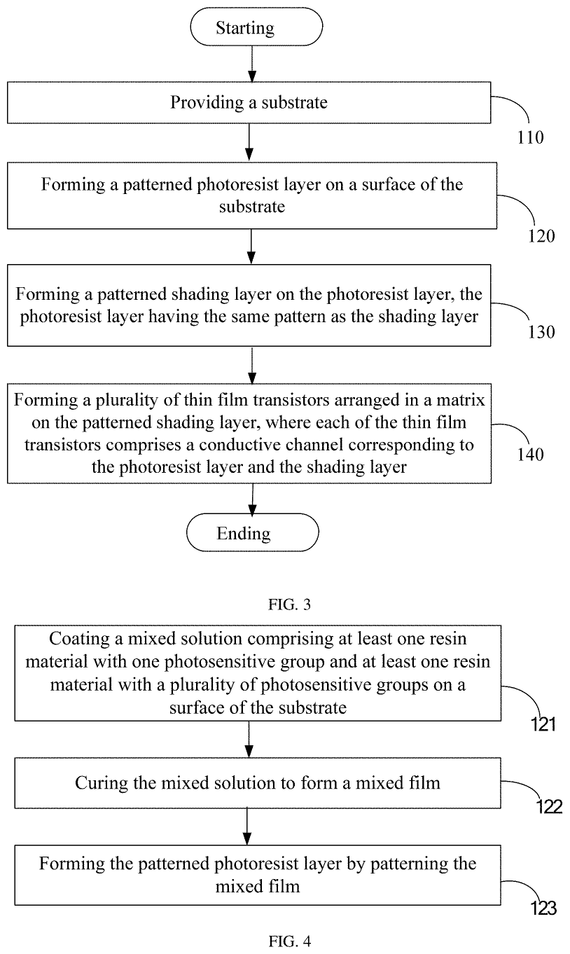

As illustrated in FIG. 3, FIG. 3 is a flowchart for manufacturing the display panel 100 as shown in FIG. 1. As illustrated in FIG. 3, a method for manufacturing the display panel 100 includes the following operations.

At block 110, a substrate 10 is provided. The substrate 10 includes a first surface 101 and a second surface 102, where the first surface 101 is opposite to the second surface 102. The first surface 101 is operated to receive light, that is, the first surface 101 is configured as a light incident surface of the display panel 100. It will be apprehended that, a light source (not shown) may be arranged one side corresponding to the first surface 101. Light emitted by the light source is configured as an image display light of the display panel 100. The incident light from the first surface 101 exits out from the second surface 102.

At block 120, a patterned photoresist layer 11 is formed on a surface of the substrate 10.

Specifically, as illustrated in FIG. 4, FIG. 4 is a flowchart for manufacturing a photoresist layer 11. As illustrated in FIG. 1 and FIG. 4, a method for manufacturing the patterned photoresist layer 11 includes the following operations.

At block 121, a mixed solution including at least one resin material with one photosensitive group and at least one resin material with a plurality of photosensitive groups is coated on a second surface 102 of the substrate 10.

At block 122, the mixed solution is cured to form a mixed film.

At block 123, the patterned photoresist layer 11 is formed by patterning the mixed film. An exposure intensity corresponding to the mixed film is gradually decreased along a direction from the mixed film to the substrate 10. The concentration of the resin material with a plurality of photosensitive groups gradually decreases along the light outlet direction of the display panel 100.

Preferably, the resin material of the plurality of photosensitive groups is capable of absorbing ultraviolet light and visible light having a wavelength smaller than a preset value.

As illustrated again in FIG. 1 and FIG. 3, at block 130, a patterned shading layer 12 is formed on the photoresist layer 11, and the photoresist layer 11 and the shading layer 12 having the same pattern.

At block 140, a plurality of thin film transistors 13 arranged in a matrix is formed on the patterned shading layer 12, where each of the thin film transistors 13 includes a conductive channel 136 corresponding to the photoresist layer 11 and the shading layer 12. The thin film transistor 13 includes a source 131, a drain 132, a semiconductor layer 133, and a gate 134. The source 131, the drain 132 are connected with the semiconductor layer 133. The source 131 and the drain 132 are arranged on two opposite sides of the semiconductor layer 133, respectively. The semiconductor layer 133 includes a conductive channel 136 of the thin film transistor 13. The conductive channel 136 is aligned with the photoresist layer 11 and the shading layer 12, that is, projections of the conductive channel 136, the photoresist layer 11, and the shading layer 12 in the first direction F on the second surface 102 of the substrate 10 are lapped each other.

The shading layer 12 can effectively prevent the light received from the first surface 101 of the substrate 10 from directly illuminating the conductive channel 136, thus avoiding a photoelectric effect generated by the conductive channel 136, which affects the operational performance of the thin film transistor 13. A refractive index of the photoresist layer 11 gradually decreases along the light outlet direction of the display panel 100. Therefore, the photoresist layer 11 refracts the light transmitted from the first surface 101 to reduce the light transmitted to the shading layer 12. Simultaneously, the photoresist layer 11 refracts the light reflected by the shading layer 12 to prevented the light reflected by the shading layer 12 from being transmitted again into the substrate 10, thus the photoresist layer 11 enables the light to be unidirectionally transmitted in the first direction F corresponding to a photic region of the display panel 100, and the light may not transmit round trip for multiple times in the substrate 10 and other layer structures, thereby effectively improving light utilization.

It will be apprehended that, the above disclosure is only the preferred embodiments of the present disclosure. Of course, the above preferred embodiments may not limit the scope of the present disclosure, and those skilled in the art can understand the implementation of all or part of the above embodiments. Equivalent variations made in accordance with the claims of the present disclosure still fall within the scope of the disclosure.

1. A display panel, comprising a substrate and a plurality of thin film transistors arranged on the substrate in a matrix, wherein the display panel further comprises a photoresist layer and a shading layer, which are arranged between each of the thin film transistors and the substrate; each of the thin film transistors comprises a conductive channel corresponding to the photoresist layer and the shading layer; the photoresist layer is more adjacent to the substrate than the shading layer; the shading layer is operated to reflect light transmitted from the substrate to prevent the light from being transmitted to the conductive channel; and the photoresist layer is operated to refract the light transmitted from the substrate and transmit the refracted light unidirectionally along a light outlet direction of the display panel.

2. The display panel of the claim 1, wherein a refractive index of the photoresist layer gradually decreases along the light outlet direction of the display panel.

3. The display panel of the claim 2, wherein the photoresist layer comprises at least one resin material with one photosensitive group and at least one resin material with a plurality of photosensitive groups, and the concentration of the resin material with a plurality of photosensitive groups gradually decreases along the light outlet direction of the display panel.

4. The display panel of the claim 3, wherein a refractive index of the resin material with a plurality of photosensitive groups is greater than a refractive index of the resin material with one photosensitive group.

5. The display panel of the claim 4, wherein the resin material with a plurality of photosensitive groups is capable of absorbing ultraviolet light and visible light having a wavelength smaller than a preset value.

6. The display panel of the claim 4, wherein the thin film transistor comprises a source, a drain, a gate, and the conductive channel; and the conductive channel is formed by a semiconductor layer arranged between the source and the drain.

7. The display panel of the claim 6, wherein the source, the drain, and the conductive channel are more adjacent to the substrate than the gate.

8. The display panel of the claim 6, wherein the gate is more adjacent to the substrate than the source, the drain, and the conductive channel.

9. A method for manufacturing a display panel, comprising:
providing a substrate;
forming a patterned photoresist layer on a surface of the substrate;
forming a patterned shading layer on the photoresist layer, the photoresist layer having the same pattern as the shading layer;
forming a plurality of thin film transistors arranged in a matrix on the patterned shading layer, wherein each of the thin film transistors comprises a conductive channel corresponding to the photoresist layer and the shading layer;
wherein the shading layer is operated to reflect light transmitted from the substrate to prevent the light from being transmitted to the conductive channel, and the photoresist layer is operated to refract light from the substrate and transmit the refracted light unidirectionally along a light outlet direction of the display panel.

10. The method for manufacturing the display panel of the claim 9, wherein the forming a patterned photoresist layer on a surface of the substrate, further comprises:
coating a mixed solution comprising at least one resin material with one photosensitive group and at least one resin material with a plurality of photosensitive groups on a surface of the substrate;
curing the mixed solution to form a mixed film; and
forming the patterned photoresist layer by patterning the mixed film.

11. The method for manufacturing the display panel of the claim 10, wherein an exposure intensity corresponding to the mixed film is gradually decreased along a direction from the mixed film to the substrate, to make the concentration of the resin material with a plurality of photosensitive groups to be gradually decreased along the light outlet direction of the display panel.

12. The method for manufacturing the display panel of the claim 11, wherein a refractive index of the photoresist layer gradually decreases along a direction away from the surface of the substrate.

13. The method for manufacturing the display panel of the claim 11, wherein a refractive index of the resin material with a plurality of photosensitive groups is greater than a refractive index of the resin material with one photosensitive group.
